(19) United States
(12) Patent Application Publication
(10) Pub. No.: US 2023/0324331 A1
(43) Pub. Date: Oct. 12, 2023

(54) SENSOR

(71) Applicant: Nippon Telegraph and Telephone Corporation, Tokyo (JP)

(72) Inventors: Katsuhiko Nishiguchi, Musashino-shi, Tokyo (JP); Jinichiro Noborisaka, Musashino-shi, Tokyo (JP); Kensaku Chida, Musashino-shi, Tokyo (JP)

(21) Appl. No.: 18/041,514

(22) PCT Filed: Sep. 8, 2020
(86) PCT No.: PCT/JP2020/033942

§ 371 Date: Feb. 13, 2023

(51) Int. Cl. G01N 27/414

(52) U.S. Cl. CPC G01N 27/4146; G01N 27/4141; G01N 27/4145

(57) ABSTRACT

A sensor of the present invention includes, in order, a first conductor layer which is made of a direct transition type semiconductor and generates an electromagnetic wave; a non-conductor layer; a second conductor layer; and a third electrode, in which a first electrode is provided on a part of a first surface of the first conductor layer opposite to the non-conductor layer side, and a second electrode is provided on the other part of the first surface. Thus, the present invention can provide a sensor which identifies and detects a substance.

### TECHNICAL FIELD

The present invention relates to a sensor using an ion-sensitive field effect transistor.

### BACKGROUND ART

An electric charge sensor which utilizes an ion-sensitive field effect transistor (ISFET) is an excellent sensor having characteristics such as integration, miniaturization, and high-speed detection. Further, since high sensitivity of the electric charge detection can also be attained by the miniaturization of the ISFET, for example, not only the “detection” of a single molecule or a DNA but also microscopic “analysis” can be expected.

As described above, since important knowledge is obtained not only from an aspect of application but also from a scientific point of view, it has been attempted to improve the sensitivity of the ISFET by miniaturization in various ways. As an example thereof, it is possible to detect a small number of DNA and a low concentration of gas using an ISFET sensor which utilizes a transistor having a nano-scale structure such as graphene (NPL 1).

### CITATION LIST

### Non Patent Literature

[NPL 1] J. Sun et al., Sience Advances, vol. 2 (2016) p.e1501518.

### SUMMARY OF INVENTION

### Technical Problem

However, it is difficult to identify a substance to be detected by an ISFET for detecting electric charges. This is due to the fact that it is substantially impossible to identify a substance by the amount of electric charges. For example, although a single carbon dioxide molecule is detected in NPL 1, this can be realized only in a test environment in which only carbon dioxide exists, and it is difficult to detect carbon dioxide in an actual environment where there is also water, oxygen, nitrogen along with carbon dioxide.

In addition, when DNA is detected in a liquid, only electric charges separated by several nm from the surface of the ISFET can be detected due to the influence of an electric double layer. Therefore, even if the electric charge density on the DNA surface (negative electric charges due to phosphoric acid) is different for each DNA, it is difficult to identify the DNA unless the amount of electric charges in the electric double layer is changed.

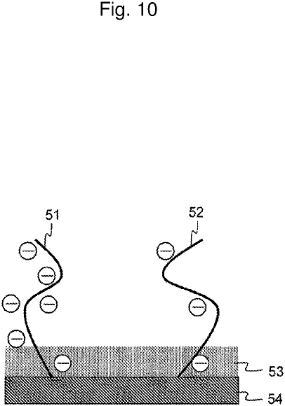

For example, as shown in FIG. 10, when the amounts of electric charges of the DNA 51 and the DNA 52 are compared, even if the amount of electric charges of the whole DNA is different, because the amount of electric charges in the electric double layer 53 is almost equal, it is difficult to identify the DNA 51 and the DNA 52 by the amount of electric charges.

Thus, the electric double layer 53 becomes a bottleneck when detecting a substance in a liquid, using the ISFET 54. For the same reason, even when a completely different charged substance such as dust adheres to the ISFET 54, it is not possible to identify the substance being detected.

As described above, an electric charge sensor using an ISFET cannot easily identify a substance it detects, and the applications that it can be used in have been limited.

### Solution to Problem

In order to solve the above problem, a sensor according to the present invention includes, in order, a first conductor layer which is made of a direct transition type semiconductor and generates electromagnetic waves, a non-conductor layer, a second conductor layer, and a third electrode, in which a first electrode is provided on a part of a first surface of the first conductor layer opposite to the non-conductor layer side, and a second electrode is provided on another part of the first surface.

### Advantageous Effects of Invention

According to the present invention, it is possible to provide a sensor which identifies and detects a substance.

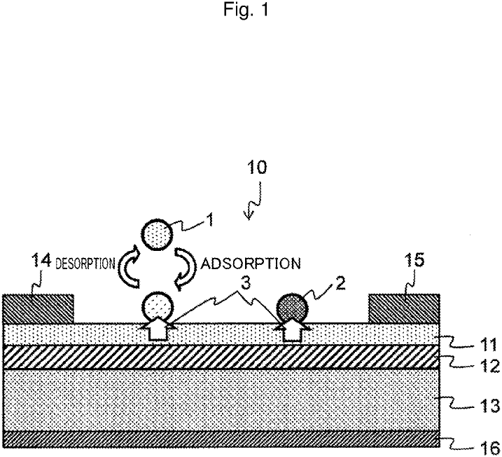

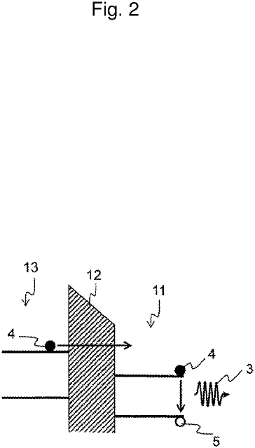

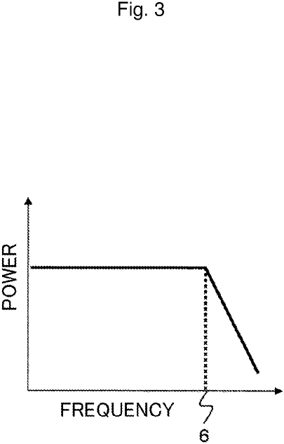

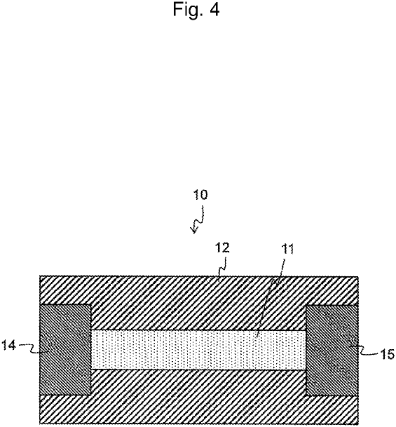

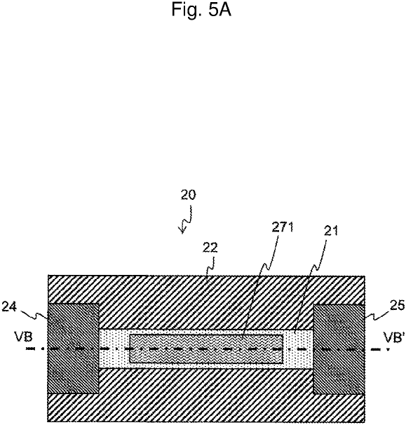

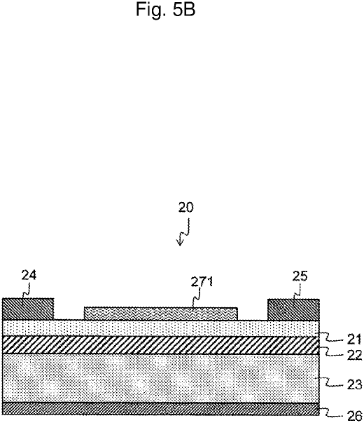

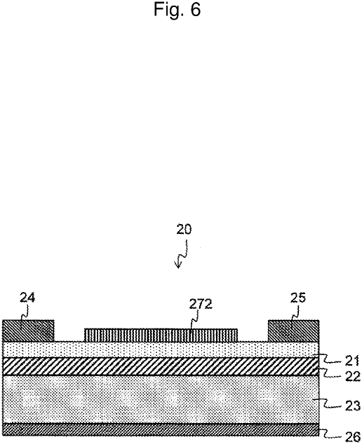

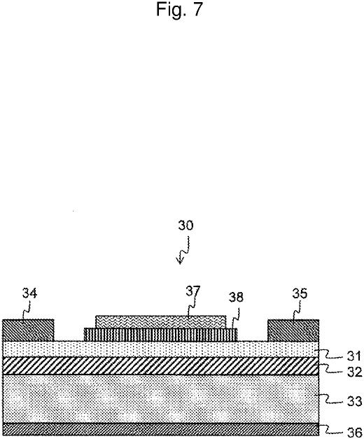

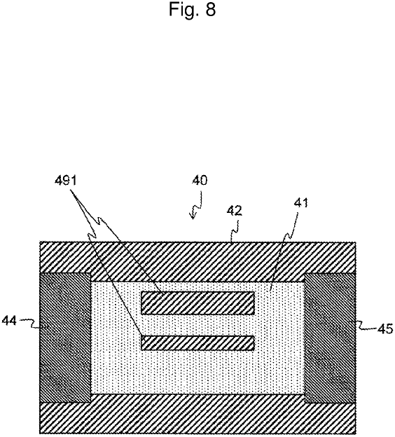

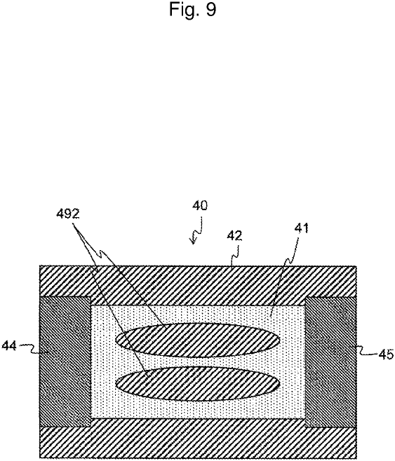

### BRIEF DESCRIPTION OF DRAWINGS

[FIG. 1]FIG. 1 is a cross-sectional schematic diagram of a sensor according to a first embodiment of the present invention.

[FIG. 2]FIG. 2 is a diagram for explaining operations of the sensor according to the first embodiment of the present invention.

[FIG. 3]FIG. 3 is a diagram for explaining the characteristics of the sensor according to the first embodiment of the present invention.

[FIG. 4]FIG. 4 is a top view of the sensor device according to the first embodiment of the present invention.

[FIG. 5A]FIG. 5A is a top view of a sensor according to a second embodiment of the present invention.

[FIG. 5B]FIG. 5B is a cross-sectional view of VB-VB of a sensor according to a second embodiment of the present invention.

[FIG. 6]FIG. 6 is a cross-sectional view of VB-VB′ of a sensor according to the second embodiment of the present invention.

[FIG. 7]FIG. 7 is a cross-sectional drawing of a sensor according to the third embodiment of the present invention.

[FIG. 8]FIG. 8 is a top view of a sensor according to a fourth embodiment of the present invention.

[FIG. 9]FIG. 9 is a top view of the sensor according to the fourth embodiment of the present invention.

[FIG. 10]FIG. 10 is a diagram for explaining detection of a DNA using an electric charge sensor of related art.

### DESCRIPTION OF EMBODIMENTS

### First Embodiment

A sensor according to a first embodiment of the present invention will be described below with reference to FIGS. 1 to 4.

### Configuration of Sensor

As shown in FIG. 1, a sensor 10 according to the present embodiment includes, in order, a first conductor layer 11, a non-conductor layer 12, and a second conductor layer 13. A first electrode 14 is provided on a part of a front surface of the first conductor layer 11 (a surface opposite to the non-conductor layer 12 side), a second electrode 15 is provided on another part, and a third electrode 16 is provided on a rear surface of the second conductor layer 13 (a surface opposite to the non-conductor layer 12 side). Here, the first conductor layer 11, the first electrode 14 and the second electrode 15 have the same configuration as the ISFET.

### Operation of Sensor

As an example of the sensor 10 according to the present embodiment, a case of being used for identifying and detecting a gas will be described.

In a case where a semiconductor, for example, a p-type semiconductor having holes as carriers, is used for the first conductor layer 11, when gas molecules are adsorbed on the surface of the semiconductor, because the resistance of the first conductor layer 11 changes due to polarization or electric charge transfer of the gas molecules, the gas molecules can be detected. At this time, one of the first electrode 14 and the second electrode 15 of the sensor 10 is connected to a positive or negative voltage, and the other is connected to the ground.

However, when there are a variety of gas molecules, a difference in the influence of the various gas molecules on the first conductor layer 11 is extremely small. Further, since these gas molecules are adsorbed to the first conductor layer 11 at random, it is extremely difficult to identify a specific kind of gas.

In order to identify and detect only a specific gas molecule, the adsorbed gas molecule 1 is irradiated with electromagnetic waves (light) 3 from the first conductor layer 11. When a substance (gas molecule 1) is irradiated with the electromagnetic waves (light) 3 and the energy of vibration or rotation of the molecules constituting the substance (gas molecule 1) matches the energy of the electromagnetic waves (light) 3, the light energy is absorbed by the substance. Since the molecular vibration or the like is a unique feature of the substance (gas molecule 1), the substance (gas molecule 1) can be identified by monitoring the absorption spectrum of the light energy.

The electromagnetic waves 3 are generated by the configurations of the first conductor layer 11, the non-conductor layer 12, and the second conductor layer 13 (Japanese Patent No. 6843629). As shown in FIG. 2, when electrons 4 are tunnel-injected from the conduction band of the second conductor layer 13 to the conduction band of the first conductor layer 11, the electrons 4 injected into the conduction band of the first conductor layer 11 are recombined with the holes 5 of the valence band of the first conductor layer 11, and the electromagnetic waves 3 reflecting the energy band structure of the first conductor layer 11 are generated.

In the sensor 10, a voltage is applied between the third electrode 16 and either one of the first electrode 14 and the second electrode 15 connected to the ground, electrons 4 are injected from the second conductor layer 13 to the first conductor layer 11, and electromagnetic waves 3 are generated.

When the gas molecule 1 is irradiated with the electromagnetic waves 3 having a wavelength absorbed by the gas molecule to be detected (gas molecule 1 of FIG. 1), the gas molecule 1 obtains energy from the electromagnetic waves 3, and desorption and adsorption are repeated at random on the surface of the first conductor layer 11.

Alternatively, in a state in which the electromagnetic waves 3 are not radiated and the gas molecules 1 repeat desorption and adsorption at random at a very low speed on the surface of the first conductor layer 11, desorption and adsorption begin to be repeated at a high speed when the electromagnetic waves 3 are radiated. In other words, the speed of desorption and adsorption of the gas molecules 1 on the surface of the first conductor layer 11 increases with the radiation of the electromagnetic waves 3.

By reflecting the desorption and adsorption of the gas molecules, the current of the ISFET in the sensor 10 is modulated. When the frequency characteristic of the ISFET current is observed by a spectrum analyzer or the like, a Lorentz-type spectrum shown in FIG. 3 can be obtained. The power of the spectrum on a vertical axis corresponds to the current of the ISFET.

A cut-off frequency (a frequency at which the power decreases) 6 of the spectrum depends on the speed of desorption and adsorption of gas molecules. The cut-off frequency 6 is observed on a highfrequency side as the speed of desorption and adsorption of gas molecules increases.

As described above, the gas molecules repeat desorption and adsorption at random speeds, but there is a limit to the speed, and the gas molecules do not desorb and adsorb at a speed higher than a certain speed. As a result, at a certain degree of speed, in other words, at the frequency, the current of the ISFET is not modulated, and the cut-off frequency 6 is observed.

Therefore, if only the gas molecule 1 which has obtained energy from the electromagnetic waves 3 is desorbed and adsorbed, the gas molecule 1 can be identified and detected by the presence or absence of the Lorentz type spectrum. As shown in FIG. 1, the gas molecules 1 are repeatedly desorbed and adsorbed by the electromagnetic waves 3. On the other hand, the gas molecule 2 does not absorb the energy of the electromagnetic wave 3 and does not desorb or adsorb it. Therefore, only the gas molecule 1 can be identified and detected.

For example, when oxygen and carbon dioxide are mixed and electromagnetic waves having a wavelength of 600 nm and 700 nm are radiated, oxygen molecules absorb the energy of the electromagnetic waves and perform desorption and adsorption, and carbon dioxide molecules do not absorb the energy of the electromagnetic waves and do not perform desorption and adsorption. As a result, only oxygen molecules can be identified and detected.

For gases other than oxygen, for example, carbon dioxide can be identified and detected using electromagnetic waves of 4,200 nm to 4,300 nm, carbon monoxide can be identified and detected using electromagnetic waves of 4,500 nm to 4,700 nm, and ammonia can be identified and detected using electromagnetic waves of 2,800 nm to 2,900 nm.

When a plurality of gas molecules are repeatedly desorbed and adsorbed due to the radiation of the electromagnetic waves 3, since a plurality of different Lorentz-type spectra are observed, the respective gas molecules can be identified and detected.

For example, when the speeds of desorption and adsorption due to the radiation of the electromagnetic waves 3 differ depending on the kind of gases, the cut-off frequency 6 different for each kind of gas is observed.

When the mode of the change of the desorption/adsorption speed due to the radiation of the electromagnetic waves 3 is different depending on the kind of gas, the mode of the change of the different cut-off frequency 6 for each kind of gas is observed. For example, when the change in speed of desorption and adsorption of the gas molecules 1 is large and the change in the speed of desorption and adsorption of the gas molecules 2 is small, the change in the cut-off frequency 6 corresponding to desorption and adsorption of the gas molecules 1 is observed to be large and the change in the cut-off frequency 6 corresponding to desorption and adsorption of the gas molecules 2 is observed to be small.

An object other than a gas can be detected using the sensor 10 according to the present embodiment. Next, a case where the target substance is DNA will be described.

When the DNA is a substance to be detected, the energy of the electromagnetic waves 3 absorbed by the DNA is different depending on the length and constitution of the DNA. Therefore, the specific DNA can be detected by radiating the electromagnetic waves 3 having energy absorbed by only the specific DNA.

As shown in FIG. 10, the DNA moves in a liquid in a thermal equilibrium state with one end not adsorbed to the surface of the sensor 10 and the other end adsorbed. When the DNA is irradiated with the electromagnetic waves 3, the DNA absorbs the energy of the electromagnetic waves 3 and moves in a thermal non-equilibrium state. As a result, the amount of electric charges of the electric double layer also changes. Therefore, a Lorentz type spectrum appears in the frequency characteristic of the current of the ISFET, and the discrimination and detection of DNA can be performed similarly to the discrimination and detection of gas molecules.

The concentration of the substance to be detected can also be evaluated by the intensity of the Lorentz-type spectrum acquired using the sensor 10 according to the present embodiment. For example, the concentration of the substance to be detected can be evaluated by referring to data such as concentration dependency of spectral intensity in the substance to be detected acquired in advance.

In the sensor 10 according to the present embodiment, the electric charge detection sensitivity can be improved by thinning the first conductor layer 11. For example, in the case of detecting a single gas molecule or DNA, the thickness of the first conductor layer 11 can be set to 0.3 nm to 10 nm, and 0.3 nm to several nm is desirable.

Further, as shown in the top view of the sensor 10 of FIG. 4, the length of the first conductor layer 11 between the first electrode 14 and the second electrode 15 can be set to be equal to or greater than about a reciprocal of the linear density of the substance to be detected, thereby improving the detection sensitivity. For example, in the case of detecting a 1 ppm trace gas in the atmosphere, the length of the first conductor layer 11 is preferably about several um.

Further, the width of the first conductor layer 11 can be set to be close to a distance at which electric charges caused by the substance to be detected affect the first conductor layer 11, thereby improving the detection sensitivity. For example, in the case of a single amount of electric charges, it is desirable to set the width of the first conductor layer 11 to about several tens of nanometers.

The thickness of the non-conductor layer 12 is preferably such that electric charges can tunnel, and it is preferably about 2 nm to 4 nm to obtain a sufficient tunnel current.

A semiconductor having a direct transition type energy band gap equivalent to the energy of the electromagnetic waves 3 which can be absorbed by the substance to be detected can be used as the material of the first conductor layer 11. For example, graphene which is a direct transition type semiconductor can adjust the band gap depending on the width of several nm to several tens of nm. Therefore, by controlling the width depending on the substance to be detected, the substance can be identified and detected. If the thickness is set to about one atomic layer (3 angstroms), good detection sensitivity is obtained as described above.

The first electrode 14 and the second electrode 15 are preferably a low-resistance metal, and are preferably capable of forming an ohmic contact with the first conductor layer 11. In the present embodiment, when the frequency characteristics are observed as described above, the series resistance (resistance between the first electrode 14 and the second electrode 15 and the first conductor layer 11) can be ignored.

A semiconductor or a metal is used for the second conductor layer 13. In the case of using a semiconductor, when electric charges are injected from the second conductor layer 13 to the first conductor layer 11, the electric charges and many electric charges of the first conductor layer 11 need to have different polarities.

For example, when the first conductor layer 11 is an n-type semiconductor, the second conductor layer 13 is a p-type semiconductor. When the first conductor layer 11 is a p-type semiconductor, the second conductor layer 13 is an n-type semiconductor. When the first conductor layer 11 is an intrinsic semiconductor, the second conductor layer 13 may be an n-type semiconductor or a p-type semiconductor. The second conductor layer 13 may be an intrinsic semiconductor.

The non-conductor layer 12 may be a titanium oxide film, a silicon nitride film or the like, in addition to a silicon oxide film, and is preferably a material having high insulation resistance.

As an example of the sensor according to the present embodiment, graphene can be used for the first conductor layer 11, silicon oxide can be used for the non-conductor layer 12, and silicon can be used for the second conductor layer 13.

### Second Embodiment

A sensor according to a second embodiment of the present invention will be described below with reference to FIGS. 5A to 6.

A sensor 20 according to the present embodiment includes a first conductor layer 21, a non-conductor layer 22, a second conductor layer 23, a first electrode 24, a second electrode 25, and a third electrode 26 as in the sensor 10 according to the first embodiment, and further, an adsorption layer 271 is provided on a part of a surface (a surface opposite to the non-conductor layer 22 side) of the first conductor layer 21.

In the sensor according to the first embodiment, the substance to be detected is limited to a substance capable of being adsorbed to the first conductor layer 21, particularly a biological substance such as DNA.

The sensor according to the present embodiment includes an adsorption layer 271 on the surface of the first conductor layer 21 as shown in FIGS. 5A and 5B to mitigate the limitation of the substance to be detected. The adsorption layer 271 is a conductor having a thiol group on a metal surface such as gold, and can adsorb a biological substance such as DNA through the thiol group.

Here, as shown in FIG. 5B, by providing an adsorption layer 271 in accordance with the substance to be detected on the first conductor layer 21 constituting the ISFET, the selectivity of the substance to be detected is also improved, and the substance can be efficiently detected. Further, by utilizing a conductor for the adsorption layer 271, electric charge information spreads over the entire adsorption layer 271, and efficient electric charge detection can also be performed.

As shown in FIG. 5A, the adsorption layer 271 may be formed in a part of the first conductor layer 21 other than the first electrode 24 and the second electrode 25, or may be formed in the entire region. The thickness of the adsorption layer 271 is preferably about several nm, which is desirable to be thin enough to transmit electromagnetic waves.

In the present embodiment, although an example in which a metal such as gold having a thiol group is used for the adsorption layer 271 is shown, a conductive RNA or an antibody may be used for the adsorption layer 271. When the conductive RNA or the antibody is used for the adsorption layer 271, the selectivity of the substance to be detected is further improved.

As shown in FIG. 6, a non-conductive material can be used for the adsorption layer 272. A material having high adsorptivity of a substance to be detected may be selected as the non-conductive material, and choices are widened compared with a conductor. For example, non-conductive RNA, DNA, antibodies, enzymes, and the like are known.

When a biological substance or the like in a liquid such as DNA is detected, when the first conductor layer 21 has low resistance to a liquid such as alkali or acid, if a non-conductive material having high resistance to these liquids is used for the adsorption layer 272, the first conductor layer 21 can be protected. Further, the electromagnetic wave can be irradiated to the substance to be detected by suppressing attenuation of the electromagnetic wave. Here, a different non-conductive material may be provided on the surface of the non-conductive material of the adsorption layer 272.

### Third Embodiment

Next, a sensor according to a third embodiment of the present invention will be described with reference to FIG. 7.

The sensor 30 according to the present embodiment includes a first conductor layer 31, a non-conductor layer 32, a third conductor layer 33, a first electrode 34, a second electrode 35, a third electrode 36, and an adsorption layer 37, as in the sensor 20 according to the second embodiment. Further, as shown in FIG. 7, a protective layer 38 is provided between the first conductor layer 31 and the adsorption layer 37.

The adsorption layer 37 is preferably a conductor.

It is desirable that the protective layer 38 has high resistance to liquids such as alkali and acid containing a substance to be detected such as DNA. For example, non-conductive RNA, DNA, antibodies, enzymes, and the like can be used. Further, a silicon oxide film, a silicon nitride film, or the like may be used in accordance with the liquid (acid and alkali) containing the substance to be detected.

According to the sensor 30 according to the present embodiment, the electric charge information spreads over the entire adsorption layer 37, enabling efficient electric charge detection, and the first conductor layer 31 can be protected by the protective layer 38.

### Fourth Embodiment

Next, a sensor according to a fourth embodiment of the present invention will be described with reference to FIGS. 8 and 9.

A sensor 40 according to the present embodiment includes a first conductor layer 41, a non-conductor layer 42, a second conductor layer 43, a first electrode 44, a second electrode 45, and a third electrode 46, as in the sensor 10 according to the first embodiment. Further, as shown in the top view of FIG. 8, the graphene of the first conductor layer 41 has an opening 491.

By forming the opening 491 in the graphene of the first conductor layer 41, the first conductor layer (graphene) 41 beside the opening 491 has a predetermined width. Here, the width of the first conductor layer (graphene) 41 beside the opening 491 is several nm to several tens of nm.

Since the energy band gap of the graphene changes by changing the width at several nm to several tens of nm, the energy (wavelength) of the generated electromagnetic wave changes.

Therefore, in the sensor 40 according to the present embodiment, by forming the opening 491 in the graphene of the first conductor layer 41 to form the graphene having different widths, it is possible to generate electromagnetic waves having different energies (multiple wavelengths).

According to the sensor 40 of the present embodiment, when a plurality of substances to be detected (gas molecules, biomaterials and the like) each absorb electromagnetic waves of different energies, since the electromagnetic waves of multiple wavelengths can be generated at a time by one sensor, a plurality of substances to be detected can be collectively identified and detected.

Further, as shown in FIG. 9, if a circular opening 492 is formed in the graphene of the first conductor layer 41, since the width of the graphene continuously changes, electromagnetic waves of multiple wavelengths can be further generated, and a plurality of substances to be detected can be collectively identified and detected.

In this embodiment, an adsorption layer may be provided on a part of the surface of the first conductor layer 41 (a surface opposite to the non-conductor layer side), as in the second embodiment. In this case as well, effects similar to those of the second embodiment can be exhibited.

In the present embodiment, a protective layer may be provided between the first conductor layer 41 and the adsorption layer, as in the third embodiment. In this case as well, effects similar to those of the third embodiment can be exhibited.

In the present embodiment, although an example in which two openings are formed in the graphene of the first conductor layer is shown, the number of openings may be single or three or more. Further, the shape of the opening may be other than a rectangular shape or a circular shape.

In the embodiment according to the present invention, although an example in which graphene is used as a direct transition type semiconductor is shown, the present invention is not limited thereto. GaAs, InP or the like may be used.

In the embodiment according to the present invention, although an example in which a p-type semiconductor is used for the first conductor layer is shown, the present invention is not limited thereto. An n-type semiconductor may be used for the first conductor layer, or an intrinsic semiconductor may be used.

In the embodiment of the present invention, in the configuration of the sensor and the like, an example of the structure, dimensions, materials and the like of each component is shown, but the present invention is not limited thereto. Any modifications can be made as long as it exerts the functions of the sensor and exhibits the effect.

### INDUSTRIAL APPLICABILITY

The present invention can be applied to an environmental field and a biomedical field as a sensor for detecting gas and a biological substance such as DNA.

Reference Signs List

| | |
|---|---|
| 10 | Sensor |
| 11 | First conductor layer |
| 12 | Non-conductor layer |
| 13 | Second conductor layer |
| 14 | First electrode |
| 15 | Second electrode |
| 16 | Third electrode |

1. A sensor comprising: in order,
a first conductor layer which is made of a direct transition type semiconductor and generates electromagnetic waves;
a non-conductor layer;
a second conductor layer; and
a third electrode,
wherein a first electrode is provided on a part of a first surface of the first conductor layer opposite to the non-conductor layer side, and
a second electrode is provided on another part of the first surface.

2. The sensor according to claim 1, wherein a voltage is applied between the third electrode and one of the first electrode or the second electrode connected to the ground to generate e electromagnetic waves, and
a substance adsorbed on the first surface is desorbed by the electromagnetic waves.

3. The sensor according to claim 2, wherein the substance is identified and detected by a cut-off frequency caused by a speed at which the substance repeats adsorption and desorption on the first surface in frequency characteristics of a current flowing between the first electrode and the second electrode.

4. The sensor according to claim 1, wherein an adsorption layer is provided on the first conductor layer.

5. The sensor according to claim 4, wherein a protective layer is provided between the first conductor layer and the adsorption layer.

6. The sensor according to claim 1, wherein the direct transition semiconductor is a graphene.

7. The sensor according to claim 6, wherein the first conductor layer has an opening.

8. The sensor according to claim 2, wherein an adsorption layer is provided on the first conductor layer.

9. The sensor according to claim 3, wherein an adsorption layer is provided on the first conductor layer.

10. The sensor according to claim 2, wherein the direct transition semiconductor is a graphene.

11. The sensor according to claim 3, wherein the direct transition semiconductor is a graphene.

12. The sensor according to claim 4, wherein the direct transition semiconductor is a graphene.

13. The sensor according to claim 5, wherein the direct transition semiconductor is a graphene.
